(19) United States
(12) Patent Application Publication
(10) Pub. No.: US 2007/0194212 A1
(43) Pub. Date: Aug. 23, 2007

(54) Ambient light photodetector

(75) Inventors: Hao-Hsiung Lin, Taipei City (TW); Da-Jung Ma, Taipei City (TW); Jiun-Yi Wu, Taipei City (TW)

Correspondence Address: BIRCH STEWART KOLASCH & BIRCH, PO BOX 747, FALLS CHURCH, VA, 22040-0747, US

(73) Assignee: National Taiwan University

(21) Appl. No.: 11/359,536

(22) Filed: Feb. 23, 2006

(51) Int. Cl. H01L 31/00

(52) U.S. Cl. 250/214.1; 250/214 AL; 257/222

(57) ABSTRACT

There is provided an ambient light photodetector, comprising a substrate, and a buffer layer formed on the substrate, an absorption layer represented by AlₓGa₁₋ₓAs where 0<×<1, formed on the buffer layer used for absorbing visible light; and a filter layer made of GaAs, formed on the absorption layer used for absorbing light between 300 nm-860 nm. Such an eye-like photodetector has a spectral response which corresponds to that of the human eye.

### BACKGROUND OF THE INVENTION

1. Field of the Invention

The present invention relates generally to a photodetector, and more particular, to an ambient light photodetector.

2. The Prior Arts

In 1924, the International Commission on Illumination (CIE) updated the photopic luminous efficiency function (maximum efficiency is at a wavelength of 555 nm) as a standard response function in accordance with the cone cells in the retina of the eye. The conventional ambient light photodetector is a photodetector which produces responses to ambient light corresponding to the photopic luminous efficiency function, or corresponding to the response of a human eye.

The ambient light photodetector has gain more attention than ever before with the development of the displays and mobile communication devices. The ambient light photodetector responds to the changes in the intensity of ambient light, and after treating the receiving signals, the ambient light photodetector is used to adjust the brightness and contrast of displays. The ambient light photodetector actuates the displays and mobile communication devices in a manner consistent with the perception of a human eye so that the fatigue and eyestrain are reduced, the low-power consumption is achieved, the operation time of the mobile communication devices is prolonged, and the lifetime of the displays is increased.

The products with the displays include cell phones, personal digital assistants (PDA), liquid crystal screens, plasma televisions, and notebook computers. The trend of the full-color screens of, for example, the cell phones and PDAs is moving in an increasingly faster pace. However, accompanying with the development of the full-color screens, the power consumption is increased. These devices would respond to the rapid changes in the intensity of ambient light. As a result, the backlight power supply would be adjusted to respond to the changes in the intensity of ambient light for these devices in order to provide brightness enough for a human eye. If the backlight power supply is adjusted with the ambient light photodetector to allow the emitted light intensity to vary with the ambient illumination, the power consumption of a cell phone and a PDA will be greatly reduced, and the power consumption can be reduced to 40%.

One example of the ambient light photodetector includes the widely used silicon-based photodetector manufactured by, for example, Agilent Technologies Inc., OSRAM, and Texas Advanced Optoelectronic Solutions. The advantage of the silicon-based photodetectors is that they can be integrated with an amplifier, and a Si IC chip for signal processing. On the other hand, the disadvantage of the silicon-based photodetectors is that they can absorb the infrared light, and the absorbed infrared light is difficult to be eliminated. For such a problem, a specific filter is provided for filtering the undesired infrared light. Alternatively, a dual-detector system is provided. By utilizing the dual-detector system that absorb light in two different wavelength intervals and by performing the signal processing, the undesired infrared light is filtered out. However, the silicon-based photodetectors have different response characteristic in comparison with that of the human eye. As a result of the different response characteristic, the silicon-based photodetectors may respond differently from the human eye as each is subjected to different lighting conditions in some cases, for example, halide lamp illumination or light bulb illumination, and thereby the application for the silicon-based photodetectors is limited.

Another example of the ambient light photodetector includes the ambient light photodetector integrated with the display panel. This ambient light photodetector is manufactured while a-Si TFT (amorphous silicon thin film transistor) process is performed to fabricate the liquid crystal panel. Alternatively, this ambient light photodetector is manufactured by using the organic LED material while the organic LED display is manufactured. If the ambient light photodetector is manufactured in such a manner, it will be beneficial to the detection arrangement and the material cost. However, the panel design will be changed if the above-mentioned manufacturing method is used. Consequently, the process for manufacturing the panel will be changed with the change of the panel design. Therefore, the method for manufacturing the ambient light photodetector integrated with the display panel is only applied to a writing panel nowadays, but not to the detection of the ambient light.

In order to solve the problems set forth above, the ambient light photodetector is manufactured by using a material which is not used to manufacture the Si IC chip and the panel. This material, which absorbs light within substantially the same wavelength range as that perceived by the human eye, is used to manufacture the ambient light photodetector. If the ambient light photodetector is manufactured by using such a material, the operation of the ambient light photodetector will be stable and repeatable, and the ambient light photodetector made of such a material will not have the same spectral response as the silicon-based photodetector, but have a spectral response which corresponds to that of the human eye. The manufacture cost of such an ambient light photodetector is cheaper than that of the conventional ambient light photodetector because the calibration of the signals and the signal processing are left out. Because the ambient light photodetector made of such a material is separately manufactured, the design of the panel will not be changed. Therefore, the whole system is more flexible. However, a suitable material used to manufacture the ambient light photodetector has not been found. It is an objective of this invention to find a suitable material used to manufacture the ambient light photodetector which actuates the device in a manner consistent with the perception of a human eye.

### SUMMARY OF THE INVENTION

The objective of the present invention is to provide an ambient light photodetector which does not absorb infrared light, and the spectral response of the ambient light photodetector is very closed to that of the human eye.

Another objective of the present invention is to provide an ambient light photodetector with simple structure, and thereby the manufacture cost of it can be reduced.

To achieve the foregoing objective, the present invention provides an ambient light photodetector, comprising a substrate; a buffer layer formed on the substrate; an absorption layer made of aluminum gallium arsenide, and formed on the buffer layer for absorbing visible light; and a filter layer made of gallium arsenide, formed on the absorption layer for absorbing light between 300 nm-860 nm , and having an energy gap lower than the energy gap of the absorption layer, wherein the absorption layer is made of high energy-gap aluminum gallium arsenide represented by the general formula AlₓGa₁₋ₓAs, where 0<x<1.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a cross-sectional view of the ambient light photodetector according to the present invention; and

FIG. 2 is a graphical representation of the comparison between the normalized responsivity spectrum measured of the ambient light photodetector according to the present invention and the photopic luminous efficiency function reported by the CIE.

### DETAILED DESCRIPTION OF THE PREFERRED EMBODIMENT

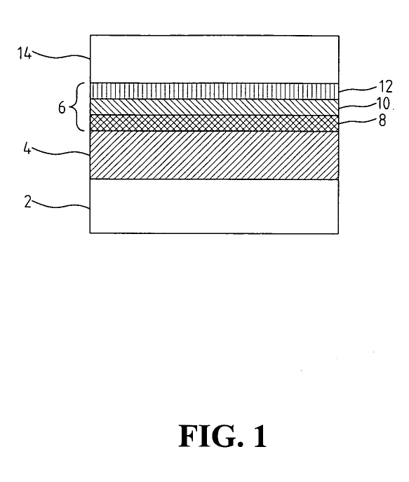

Referring to FIG. 1, the ambient light photodetector of the present invention comprises a substrate 2; a buffer layer 4 formed on the substrate 2; an absorption layer 6 formed on the buffer layer 4 for absorbing visible light; and a filter layer 14 formed on the absorption layer 6 for absorbing light between 300 nm-860 nm . The filter layer 14 can be used as a contact layer.

The absorption layer 6, which is an element of PIN (P-type-Intrinsic-N-type) photodetector, comprises the first absorption sublayer 8, the second absorption sublayer 10, and the third absorption sublayer 12 sequentially formed on the buffer layer 4, and the first absorption sublayer 8 is directly in contact with the buffer layer 4. The absorption layer 6 is made of aluminum gallium arsenide represented by the general formula AlₓGa₁₋ₓAs, where 0<x<1, more preferably 0.2<x<0.8, and most preferably 0.4<x<0.65. Furthermore, the filter layer 14 is made of gallium arsenide (GaAs).

The filter layer 14 and the substrate 2 are p-type or n-type, respectively, and are in an opposite doping type to each other. Moreover, the first absorption sublayer 8 and the third absorption sublayer 12 are p-type or n-type, respectively, and are in an opposite doping type to each other. Furthermore, the third absorption sublayer 12 and the filter layer 14 have the same doping type. Moreover, the substrate 2, the buffer layer 4, and the first absorption sublayer 8 have the same doping type, and the second absorption sublayer 10 is undoped. For example, if the substrate 2 is n-type, the first absorption sublayer 8 is also n-type, and the third absorption sublayer 12 and the filter layer 14 are p-type. On the other hand, if the substrate 2 is p-type, the first absorption sublayer 8 is also p-type, and the third absorption sublayer 12 and the filter layer 14 are n-type. Furthermore, the two bias electrodes are in contact with the filter layer 14 and the substrate 2, respectively.

Because the energy gap of the filter layer 14 is lower than that of the absorption layer 6 in the ambient light photodetector of the present invention, the free carriers generated by light absorbed by the filter layer 14 can not be converted into the photocurrent due to the energy barrier. Only the free carriers generated by light absorbed by the absorption layer 6 can be converted into the photocurrent. Moreover, if the light wavelength becomes shorter, the light will be more easily to be absorbed by the filter layer 14, and if the light is easily to be absorbed by the filter layer 14, the light will only penetrate a short distance into filter layer 14. If the thickness of the filter layer 14 is increased, less light will reach the absorption layer 6, and particularly the amount of the short wavelength light will reach the absorption layer 6 less than that of the long wavelength light. Therefore, if the thickness of the filter layer 14 is increased, the responsivity of the ambient light photodetector of the present invention will be reduced, and the peak in the responsivity spectrum will be red-shifted. On the other hand, if the thickness of the filter layer 14 is decreased, more light will reach the absorption layer 6, and also the responsivity of the ambient light photodetector of the present invention will be increased, and the peak in the responsivity spectrum will be blue-shifted. Therefore, the responsivity of the ambient light photodetector of the present invention and the peak position in the responsivity spectrum will be varied with the variations in the thickness of the filter layer 14. In order to achieve a spectral response which corresponds to that of the human eye, the thickness of the filter layer 14 is preferably 0.05-0.4 μm, more preferably 0.1-0.2 μm, and most preferably 0.12-0.15 μm.

### EXAMPLE 1

An n-type doped gallium arsenide (GaAs) substrate is formed by conventional epitaxial growth. Subsequently, a 100 nm thick n-type doped GaAs buffer layer with a carrier concentration of 10¹⁸/cm³ is formed on the substrate. Then, an absorption layer is formed on the buffer layer. The absorption layer is composed of the first absorption sublayer, the second absorption sublayer, and the third absorption sublayer. The 200 nm thick first absorption sublayer is made of aluminum gallium arsenide represented by the general formula AlₓGa₁₋ₓAs, where x=0.53, which has an n-doping concentration of 10¹⁸/cm³. The 300 nm thick second absorption sublayer is made of aluminum gallium arsenide. The 200 nm thick third absorption sublayer is made of aluminum gallium arsenide, which has a p-doping concentration of 10¹⁸/cm³. Then, the 120-150 nm thick filter layer, which is made of GaAs and has a p-doping concentration of 10¹⁸/cm³, is formed on the absorption layer. Finally, the ambient light photodetector of the present invention is obtained. The ambient light photodetector of the present invention is called hereinafter the “Al_{0.53}Ga_{0.47}As ambient light photodetector”.

The spectral responsivity of the Al_{0.53}Ga_{0.47}As ambient light photodetector is measured. The spectral responsivity is measured on an electrical probe setup. A 200 W xenon lamp (ASB-XE-175EX) is used as a light source. The light is focused by two sets of lenses and then passes the 250 Hz chopper used for light modulation into the SPEX 500M Spectrometer to separate the incident light into various monochromatic lights, so that the different photocurrents are generated when the different wavelength lights are absorbed by the photodetector. The photocurrents are amplified by an amplifier (Standard Research SR 570) and converted into voltage signals, and then are further amplified and demodulated with a lock-in amplifier (Standard Research SR 530). The output of the measurement is then recorded within a range of wavelengths.

The spectral responsivity of the Al_{0.53}Ga_{0.47}As ambient light photodetector as a sample is calibrated by using a standard silicon detector (Newport 818UV) as a reference in order to obtain the spectral responsivity (R_{pd}) of the Al_{0.53}Ga_{0.47}As ambient light photodetector. The absolute spectral responsivity of the Al_{0.53}Ga_{0.47}As ambient light photodetector can be obtained after calibrated by the standard silicon detector because the luminous intensities per unit area of the Al_{0.53}Ga_{0.47}As ambient light photodetector are the same as those of the standard silicon detector. Negative bias −2V is applied to the detector, and the sensitivity of SR570 amplifier is set to 1 μA/V.

The result shows there is a maximum sensitivity at a wavelength of 556.5 nm in the responsivity spectrum measured of the Al_{0.53}Ga_{0.47}As ambient light photodetector, and the spectral responsivity for the peak at 556.5 nm is 0.05 A/W, and the peak halfwidth is 104 nm.

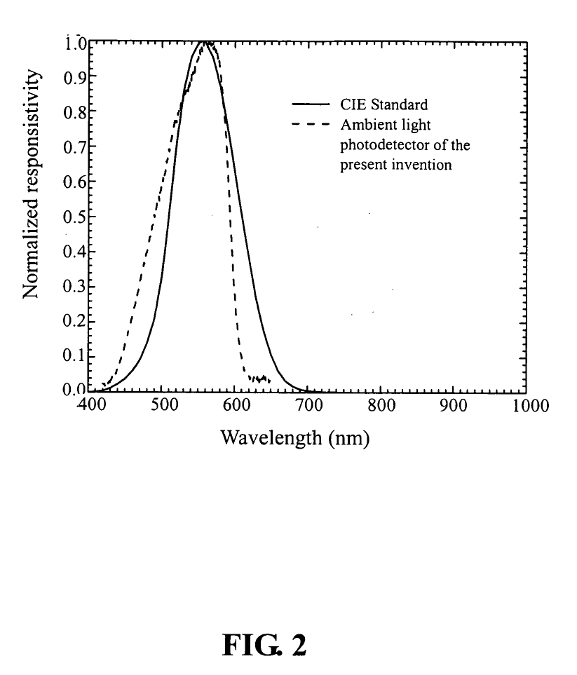

This responsivity spectrum measured of the Al_{0.53}Ga_{0.47}As ambient light photodetector is then normalized, and the normalized responsivity spectrum is in comparison with the photopic luminous efficiency function reported by the CIE. The result is shown in FIG. 2.

FIG. 2 shows the normalized responsivity spectrum measured of the Al_{0.53}Ga_{0.47}As ambient light photodetector is very closed to the photopic luminous efficiency function reported by the CIE.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. An ambient light photodetector, comprising:
a substrate;
a buffer layer formed on the substrate;
an absorption layer made of aluminum gallium arsenide represented by the general formula AlₓGa₁₋ₓAs where 0<x<1, and formed on the buffer layer for absorbing visible light; and
a filter layer made of gallium arsenide, and formed on the absorption layer for absorbing light between 300 nm-860 nm, which has a thickness of 0.05-0.4□m and an energy gap lower than the energy gap of the absorption layer.

2. The photodetector as claimed in claim 1, wherein the filter layer and the substrate are p-type or n-type, respectively, and are in an opposite doping type to each other.

3. The photodetector as claimed in claim 1, wherein two bias electrodes are in contact with the filter layer and the substrate, respectively.

4. The photodetector as claimed in claim 1, wherein the absorption layer is made of aluminum gallium arsenide represented by the general formula AlₓGa₁₋ₓAs, where 0.2<x<0.8.

5. The photodetector as claimed in claim 1, wherein the absorption layer is made of aluminum gallium arsenide represented by the general formula AlₓGa₁₋ₓAs, where 0.4<x<0.65.

6. The photodetector as claimed in claim 1, wherein the substrate is n-type.

7. The photodetector as claimed in claim 1, wherein the filter layer has a thickness of 0.1-0.2 μm.

8. The photodetector as claimed in claim 1, wherein the filter layer has a thickness of 0.12-0.15 μm.
